(19) United States
(12) Patent Application Publication
(10) Pub. No.: US 2006/0272885 A1
(43) Pub. Date: Dec. 7, 2006

(54) Length-adjustable cabinet

(76) Inventor: Ping-Yu Lee, Taoyuan (TW)

Correspondence Address: SCHMEISER, OLSEN & WATTS, 22 CENTURY HILL DRIVE, SUITE 302, LATHAM, NY, 12110, US

(21) Appl. No.: 11/146,806

(22) Filed: Jun. 7, 2005

(51) Int. Cl. H05K 5/00; A47B 81/06

(52) U.S. Cl. 181/199; 181/148; 181/156

(57) ABSTRACT

A length-adjustable cabinet includes at least a first enclosure and a second enclosure. The second enclosure can be telescoped into and fitly received in the first enclosure to reduce an overall length and volume of the cabinet, or pulled outward relative to the first enclosure to a predetermined extended position to increase the overall length of the cabinet for the latter to provide enhanced low-frequency sound effect. And, a diaphragm is mounted to a free open end of the first or the second enclosure.

### FIELD OF THE INVENTION

The present invention relates to a cabinet, and more particularly to a length-adjustable cabinet having a second enclosure that can be telescoped into a first enclosure to reduce an overall volume of the cabinet or pulled out of the first enclosure to increase an overall length and inner space of the cabinet to enhance the low-frequency sound effect.

### BACKGROUND OF THE INVENTION

A cabinet has very important influence on the sound output from a speaker. The volume, the tone, the timbre, and the audio frequency of the output sound are also determined by the quality of the cabinet. People living in the modern society with increasingly upgraded living quality require for a cabinet that produces clear sound not only with high fidelity, but also with sufficient intensity, richness, and harmony. General cabinets do not provide good low-frequency sound effect due to physical limitation in size. However, for most music lovers, low-frequency sound is indispensable. Therefore, it is a basic requirement of a cabinet to provide good low-frequency sound effect.

For the purpose of producing good timbre and low-frequency sound effect, most conventional cabinets must have a required size and volume. However, the recently developed electronic products, including the cabinets, are usually lightweight and compact. Basically, the timbre and tonality of sound output from a speaker is affected by the resonant frequency wave of number of the cabinet. When the cabinet has a reduced volume to meet the spatial limitation, the range of wavelength of the standing wave in the cabinet is also reduced to adversely affect the low-frequency sound effect. When it is desired to increase the range of wavelength of the standing wave in the cabinet to enable good low-frequency sound effect, it is necessary to increase the internal volume of the cabinet. In this case, the cabinet shall have a relatively large volume compared with other peripherals to produce unpleasant visual effect and difficulty in moving it.

It is therefore tried by the inventor to develop a length-adjustable cabinet to overcome the problems existed in the conventional cabinets.

### SUMMARY OF THE INVENTION

A primary object of the present invention is to provide a length-adjustable cabinet that can be telescoped or folded to reduce an overall length and volume, or outward pulled to increase the length of the cabinet for the same to provide enhanced low-frequency sound effect.

To achieve the above and other objects, the length-adjustable cabinet according to the present invention includes at least a first enclosure and a second enclosure. The second enclosure can be telescoped into and fitly received in the first enclosure to reduce an overall length and volume of the cabinet, or pulled outward relative to the first enclosure to a predetermined extended position to increase the overall length of the cabinet for the latter to provide enhanced low-frequency sound effect. And, a diaphragm is mounted to a free open end of the first or the second enclosure.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is an exploded perspective view of a length-adjustable cabinet according to a first embodiment of the present invention;

FIG. 2 is an assembled perspective view of the length-adjustable cabinet of FIG. 1 in a fully telescoped state;

FIG. 3 is an assembled perspective view of the length-adjustable cabinet of FIG. 1 in a fully extended state;

FIG. 4 is a sectioned side view of FIG. 2;

FIG. 5 is a sectioned side view of FIG. 3;

FIG. 6 is an exploded perspective view of a length-adjustable cabinet according to a second embodiment of the present invention;

FIG. 7 is an assembled perspective view of the length-adjustable cabinet of FIG. 6 in a fully telescoped state;

FIG. 8 is an assembled perspective view of the length-adjustable cabinet of FIG. 6 in a fully extended state;

FIG. 9 is a sectioned side view of FIG. 7;

FIG. 10 is a sectioned side view of FIG. 8;

FIG. 11 is an assembled perspective view of a length-adjustable cabinet according to a third embodiment of the present invention in a fully extended state;

FIG. 12 is a sectioned side view of FIG. 11;

FIG. 13 is an assembled perspective view of the length-adjustable cabinet of FIG. 11 in a fully folded state; and

FIG. 14 is a sectioned side view of FIG. 13.

### DETAILED DESCRIPTION OF THE PREFERRED EMBODIMENTS

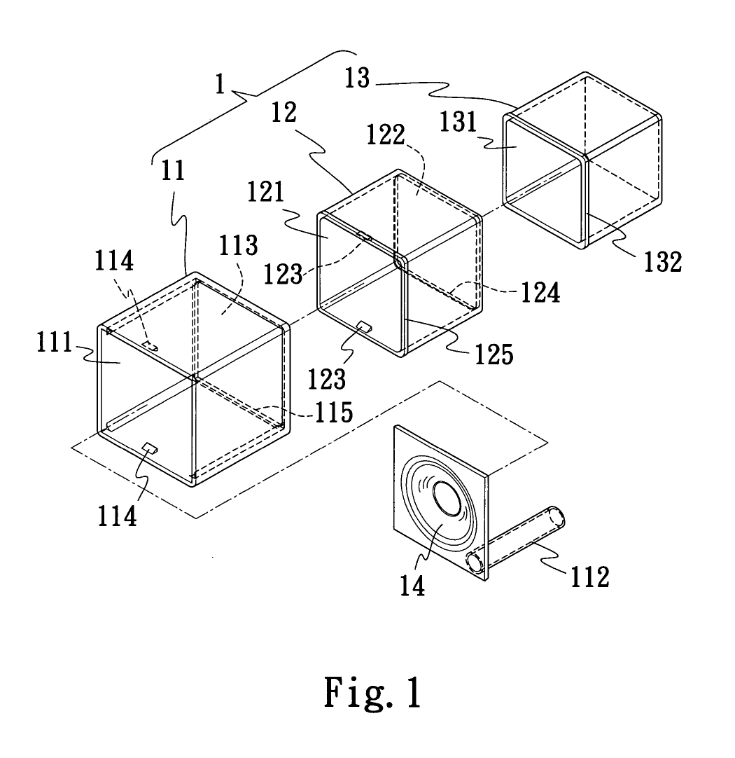

Please refer to FIGS. 1 to 5, in which a length-adjustable cabinet 1 according to a first embodiment of the present invention is shown. The length-adjustable cabinet 1 includes a first enclosure 11, a second enclosure 12, a third enclosure 13, and a diaphragm 14. The first enclosure 11 has a front opening 111 closed by the diaphragm 14. A sound pipe 112 is provided in the first enclosure 11 with a front end connected to a rear side of the diaphragm 14, so that sound wave and sound pressure could be diffused from the sound pipe 112. The sound pipe 112 may be made of a rigid material to have a mechanical structure enabling length adjustment thereof. When the sound pipe 112 is adjusted to an increased length, it is possible to enhance the quality of compass of low-frequency sounds. Alternatively, the sound pipe 112 may be made of a soft material to enable extension or compression of the sound pipe 112.

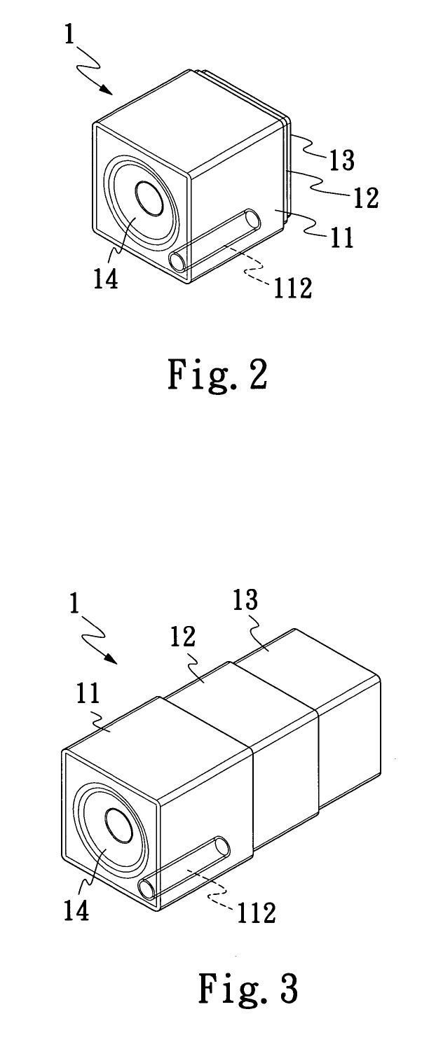

The first enclosure 11 also has a rear opening 113 facing a front opening 121 of the second enclosure 12, so that the second enclosure 12 may be telescoped into and fitly received in the first enclosure 11 via the rear opening 113. The second enclosure 12 also defines a rear opening 122 facing a front and the only opening 131 of the third enclosure 13, so that the third enclosure 13 may be telescoped into and fitly received in the second enclosure 12 via the rear opening 122, as shown in FIG. 2. As can be seen from FIG. 3, the second enclosure 12 may be outward pulled by a predetermined distance relative to the first enclosure 11, and the third enclosure 13 may be outward pulled by a predetermined distance relative to the second enclosure 12, making the cabinet 1 has an increased overall length to provide better low-frequency sound effect.

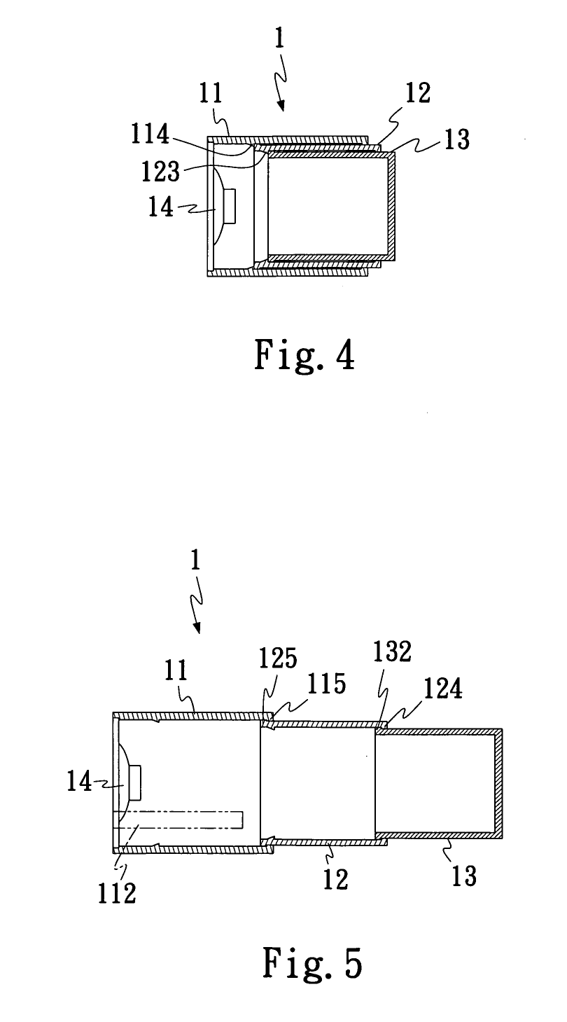

As can be seen from FIG. 4, which is a sectioned side view of FIG. 2, the first and the second enclosure 11, 12 are internally provided at predetermined locations with positioning means 114, 123, respectively, which may be stop blocks, for example, such that when the length-adjustable cabinet 1 is in a fully telescoped state as shown in FIGS. 2 and 4, the second and the third enclosure 12, 13 still have a small rear portion exposed from the rear opening 113 of the first enclosure 11 and the rear opening 122 of the second enclosure 12, respectively, allowing the second and the third enclosure 12, 13 to be rearward pulled easily as necessary.

As can be seen from FIG. 5, which is a sectioned side view of FIG. 3, the first enclosure 11 is provided along the rear opening 113 with a radially inward protruded stop block 115, and the second enclosure 12 is provided along the front opening 121 with a radially outward protruded stop block 125, such that the stop block 125 abuts on the stop block 115 when the second enclosure 12 is fully pulled rearward from the first enclosure 11, preventing the second enclosure 12 from completely separating from the first enclosure 11. Similarly, the second enclosure 12 is provided along the rear opening 122 with a radially inward protruded stop block 124, and the third enclosure 13 is provided along the only front opening 131 with a radially outward protruded stop block 132, such that when the third enclosure 13 is fully pulled rearward from the second enclosure 12, preventing the third enclosure 13 from completely separating from the second enclosure 12.

Since the second enclosure 12 can be telescoped into and fitly received in the first enclosure, and the third enclosure 13 can be telescoped into and fitly received in the second enclosure 12, the length-adjustable cabinet 1 has a largely reduced volume when it is in the fully telescoped state and can be conveniently portable. When the cabinet 1 has an internal volume smaller than a certain limit, the tone of the sound is substantially determined by the internal volume and a loop of the cabinet 1 and has high fidelity. And, when the second enclosure 12 is fully pulled from the first enclosure 11 and the third enclosure 13 from the second enclosure 12, the cabinet 1 has an extended length and accordingly an increased internal volume. In this case, a standing wave inside the cabinet 1 has an enlarged range of wavelength to enable an enhanced resonance effect of the low-frequency sound.

In the illustrated first embodiment, there are three enclosures 11, 12, 13 included in the length-adjustable cabinet 1. However, it is understood the cabinet 1 may include two or more enclosures depending on an actual requirement for the tone.

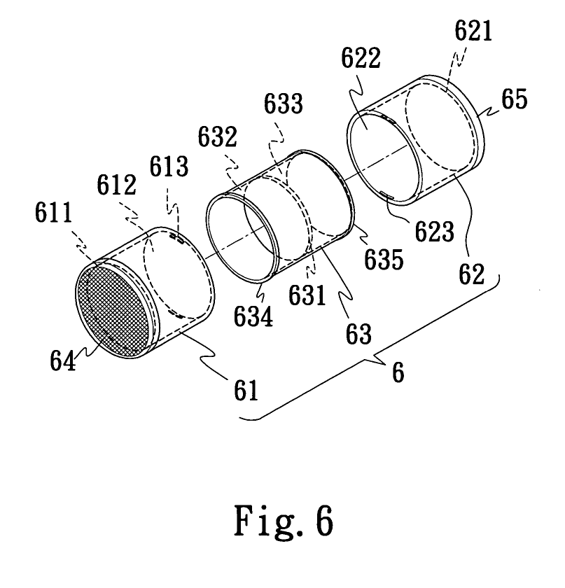

Please refer to FIGS. 6 to 10, in which a length-adjustable cabinet 6 according to a second embodiment of the present invention is shown. The length-adjustable cabinet 6 includes a first enclosure 61 having a first diaphragm 64 mounted to a front opening 611 thereof, a second enclosure 62 having a second diaphragm 65 mounted to a rear opening 621 thereof, and a third enclosure 63 made of a rigid material and having a partition 631 mounted therein to divide an inner space of the third enclosure 63 into two chambers, namely, a front chamber 632 and a rear chamber 633 that communicate with the first and the second enclosure 61, 62, respectively. The third enclosure 63 is located between the first and the second enclosure 61, 62, and the first and the second diaphragm 64, 65 are located at front and rear ends, respectively, of the length-adjustable cabinet 6. That is, the length-adjustable cabinet 6 has two speakers provided thereon.

Both the first and the second enclosure 61, 62 have a sound pipe (not shown) provided therein to connect to the first and the second diaphragm 64, 65, respectively, so that sound wave and sound pressure may be diffused from the sound pipes. The sound pipes may be made of a rigid material to have a mechanical structure enabling length adjustment thereof. When the sound pipes are adjusted to an increased length, it is possible to enhance the quality of compass of low-frequency sounds. Alternatively, the sound pipes may be made of a soft material to enable extension or compression of the sound pipes. With the partition 631, the audio frequencies produced by the first and the second diaphragm 64, 65 do not interfere with each other, and any accent is maintained.

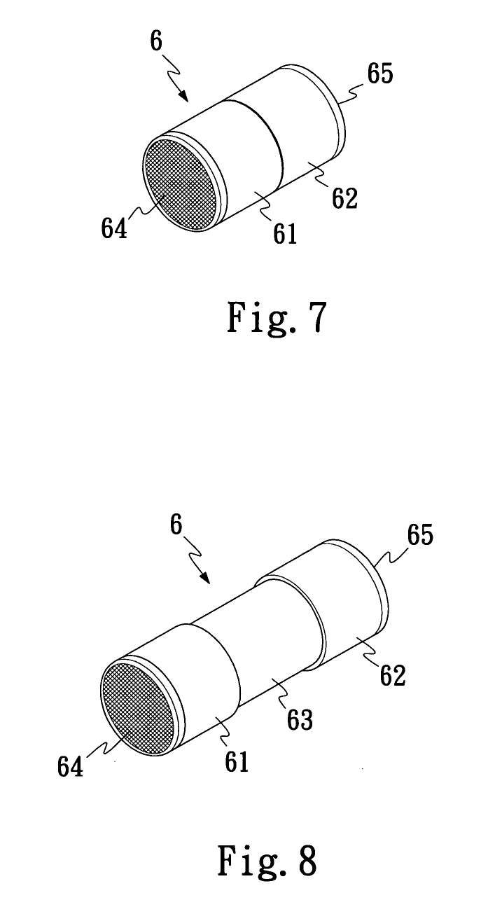

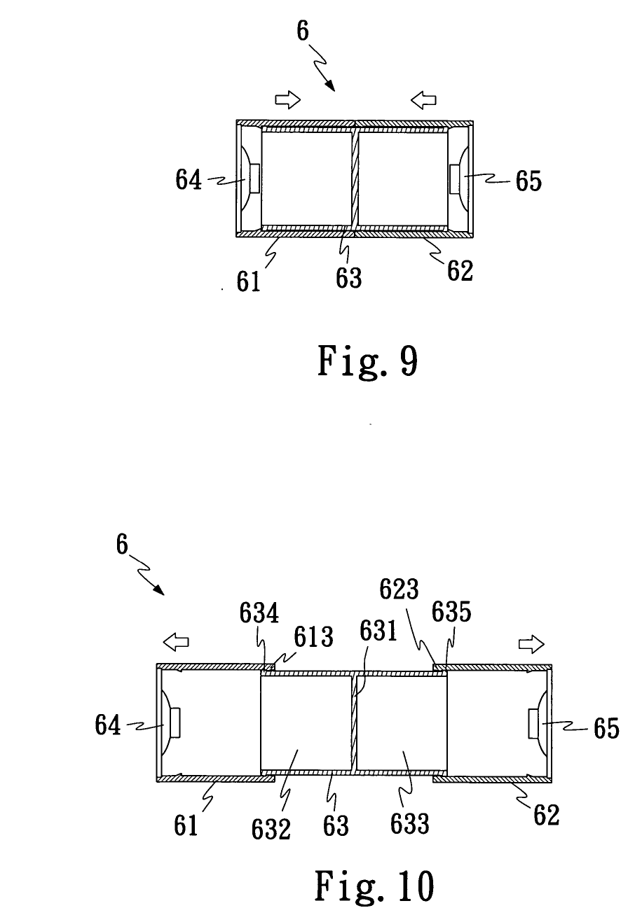

The front and the rear chamber 632, 633 of the third enclosure 63 may be telescoped into and fitly received in the first and the second enclosure 61, 62, respectively, via a rear and a front opening 612, 622 of the first and the second enclosure 61, 62, respectively, as shown in FIGS. 7 and 9, so that the length-adjustable cabinet 6 is in a fully telescoped state. When the first and the second enclosure 61, 62 are pulled relative to the third enclosure 63 to predetermined positions, as shown in FIGS. 8 and 10, the cabinet 6 has an increased overall length to enable an enhanced low-frequency sound effect.

Please refer to FIG. 10 that is a sectioned side view of the length-adjustable cabinet 6 in a fully extended state. As shown, the first and the second enclosure 61, 62 are internally provided at predetermined locations with positioning means, such as stop blocks. Moreover, the first enclosure 61 is provided at the rear opening 612 with a radially inward protruded stop block 613, and the third enclosure 63 is provided along a front opening of the front chamber 632 with a radially outward protruded stop block 634, such that the stop block 613 abuts on the stop block 634 when the first enclosure 61 is fully pulled forward from the third enclosure 63, preventing the first enclosure 61 from completely separating from the third enclosure 63. Similarly, the second enclosure 62 is provided along the front opening 622 with a radially inward protruded stop block 623, and the third enclosure 63 is provided along a rear opening of the rear chamber 633 with a radially outward protruded stop block 635, such that the stop block 623 abuts on the stop block 635 when the second enclosure 62 is fully pulled rearward from the third enclosure 63, preventing the second enclosure 62 from completely separating from the third enclosure 63.

Since the front and the rear chamber 632, 633 of the third enclosure 63 can be telescoped into and fitly received in the first and the second enclosure 61, 62, respectively, the length-adjustable cabinet 6 has a largely reduced volume when it is in the fully telescoped state and can be conveniently portable. When the cabinet 6 has an internal volume smaller than a certain limit, the tone of the sound is substantially determined by the internal volume and a loop of the cabinet 6 and has high fidelity. And, when the first and the second enclosure 61, 62 are fully pulled from the front and the rear chamber 632, 633 of the third enclosure 63, respectively, the cabinet 6 has an extended length and accordingly an increased internal volume. In this case, a standing wave inside the cabinet 6 has an enlarged range of wavelength to enable an enhanced resonance effect of the low-frequency sound.

In the illustrated second embodiment, there are three enclosures 61, 62, 63 included in the length-adjustable cabinet 6. However, it is understood the cabinet 6 may include three or more enclosures depending on an actual requirement for the tone.

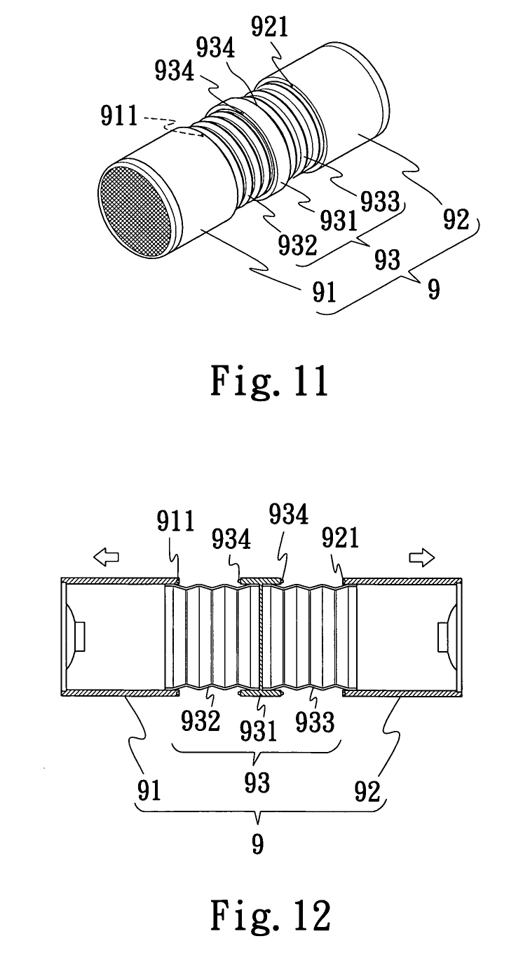

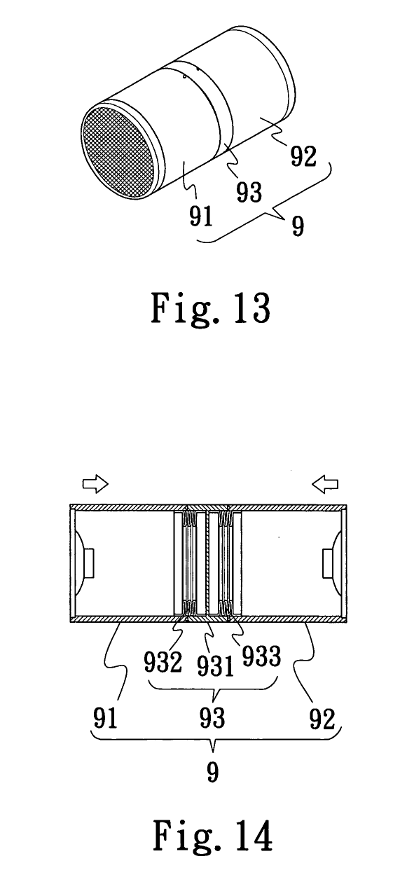

Please refer to FIGS. 11 to 14, in which a length-adjustable cabinet 9 according to a third embodiment of the present invention is shown. The length-adjustable cabinet 9 is structurally similar to the second embodiment and includes a first, a second, and a third enclosure 91, 92, 93. However, the third enclosure 93 is made of a soft material and has a partition 931 mounted therein to divide an inner space of the third enclosure 93 into two chambers, namely, a front chamber 932 and a rear chamber 933 that communicate with the first and the second enclosure 91, 92, respectively. Since the third enclosure 93 is made of a soft material, the front and the rear chamber 932, 933 may be folded as a bellows to be received in the first and the second enclosure 91, 92, respectively, as shown in FIGS. 13, 14.

Please refer to FIGS. 11 and 12 that are perspective and sectioned side views, respectively, of the length-adjustable cabinet 9 in a fully extended state. As shown, the first and the second enclosure 91, 92 are provided along a rear and a front opening, respectively, with first joining means 911, 921; and the third enclosure 93 is provided along a front and a rear end of the partition 931 with second joining means 934 corresponding to the first joining means 911, 921, respectively. Whereby, when the length-adjustable cabinet 9 is in a fully folded state with the front and the rear chamber 932, 933 of the third enclosure 93 received in the first and the second enclosure 91, 92, respectively, the first joining means 911, 921 are engaged with the second joining means 934 to hold the three enclosures 91, 92, 93 in the folded state without the risk of separating from one another, as shown in FIGS. 13, 14.

Since the front and the rear chamber 932, 933 of the third enclosure 93 can be folded and fitly received in the first and the second enclosure 91, 92, respectively, the length-adjustable cabinet 9 has a largely reduced volume when it is in the fully folded state and can be conveniently portable. When the cabinet 9 has an internal volume smaller than a certain limit, the tone of the sound is substantially determined by the internal volume and a loop of the cabinet 9 and has high fidelity. And, when the first and the second enclosure 91, 92 are fully pulled from the front and the rear chamber 932, 933 of the third enclosure 93, respectively, the cabinet 9 has an extended length and accordingly an increased internal volume. In this case, a standing wave inside the cabinet 9 has an enlarged range of wavelength to enable an enhanced resonance effect of the low-frequency sound.

In the illustrated third embodiment, there are three enclosures 91, 92, 93 included in the length-adjustable cabinet 9. However, it is understood the cabinet 9 may include three or more enclosures depending on an actual requirement for the tone.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A length-adjustable cabinet, comprising at least two enclosures, namely, a first and a second enclosure, and a first diaphragm mounted to a free open end of one of said first and second enclosures; wherein said second enclosure can be telescoped into and fitly received in said first enclosure, and outward pulled by a predetermined distance relative to the first cabinet, giving said cabinet an increased overall length to provide better low-frequency sound effect.

2. The length-adjustable cabinet as claimed in claim 1, further comprising a sound pipe connected to said first diaphragm.

3. The length-adjustable cabinet as claimed in claim 1, wherein both said first and second enclosures are internally provided at predetermined locations with positioning means.

4. The length-adjustable cabinet as claimed in claim 1, further comprising a partition located between said first and said second enclosure; and a second diaphragm mounted to a free open end of the other one of said first and second enclosures.

5. The length-adjustable cabinet as claimed in claim 4, further comprising a third enclosure, in which said partition is mounted to divide an inner space of said third enclosure into a front and a rear chamber communicable with said first and said second enclosure, respectively; said third enclosure being made of a rigid material allowing said front and said rear chamber of said third enclosure to be telescoped into and fitly received in said first and said second enclosure, respectively.

6. The length-adjustable cabinet as claimed in claim 4, further comprising a third enclosure, in which said partition is mounted to divide an inner space of said third enclosure into a front and a rear chamber communicable with said first and said second enclosure, respectively; said third enclosure being made of a soft material, allowing said front and said rear chamber of said third enclosure to be folded and fitly received in said first and said second enclosure, respectively.

7. The length-adjustable cabinet as claimed in claim 4, wherein said first and said second enclosure are internally provided with a sound pipe each to connect to said first and said second diaphragm, respectively.

8. The length-adjustable cabinet as claimed in claim 5, wherein both said first and second enclosures are internally provided at predetermined locations with positioning means.

9. The length-adjustable cabinet as claimed in claim 6, wherein both said first and second enclosure are provided with first joining means, and said third cabinet is provided with second joining means corresponding to said first joining means; whereby when said length-adjustable cabinet is in a fully folded state with said front and said rear chamber of said third enclosure folded and received in said first and said second enclosure, respectively, said second joining means are engaged with said first joining means to hold said first, second, and third enclosures to the fully folded state without the risk of separating from one another.
